(19) United States
(12) Patent Application Publication
(10) Pub. No.: US 2004/0228091 A1
(43) Pub. Date: Nov. 18, 2004

(54) Information processing apparatus and fan control method

(76) Inventor: Tatsuya Miyairi, Ome-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/807,309

(22) Filed: Mar. 24, 2004

(30) Foreign Application Priority Data
Mar. 31, 2003 (JP) 2003-096299

(51) Int. Cl. H05K 7/20

(52) U.S. Cl. 361/695; 700/300; 700/17

(57) ABSTRACT

An information processing apparatus comprises a CPU, a fan which cools the CPU, a first unit which accepts an input operation by a user, a second unit which determines a number of revolutions of the fan according to the input operation accepted by the first unit, and a third unit which controls the number of revolutions of the fan on the basis of a determined number of revolutions.

### CROSS-REFERENCE TO RELATED APPLICATIONS

This application is based upon and claims the benefit of priority from prior Japanese Patent Application No. 2003-096299, filed Mar. 31, 2003, the entire contents of which are incorporated herein by reference.

### BACKGROUND OF THE INVENTION

1. Field of the Invention

The present invention relates to an information processing apparatus having a fan control function of controlling the number of revolutions of a fan for cooling a CPU by monitoring the temperature of the CPU, and a fan control method.

2. Description of the Related Art

In information processing apparatuses such as personal computers, recently, heat generation of a CPU and the like tends to increase more and more along with the trend of higher processing speed, advanced performance, multiple function, enhanced density and the like. In this background, the cooling fan provided in a casing tends to be larger in size and higher in speed, and the fan noise is a serious problem. To solve this problem, hitherto, various fan control mechanisms have been developed for controlling the number of revolutions of the fan for cooling the CPU by monitoring the CPU temperature (see, for example, U.S. Pat. No. 6,348,873).

Conventionally, in a system having such a fan control mechanism, the maximum number of revolutions of the fan has been set as a value specific for the system (as eigenvalue) in each system (model). That is, in a conventional system, the maximum number of revolutions of the fan has been fixed regardless of the type of application, load or the like. In an application accompanied by sound (such as playback of music CD or DVD), in particular, the noise of high speed rotation of the motor has been a serious problem.

### BRIEF SUMMARY OF THE INVENTION

According to an aspect of the present invention, there is provided an information processing apparatus having a setting function for setting the sound level of high speed rotation of the fan arbitrarily by the user by a simple operation, and a fan control method.

An information processing apparatus according to a first aspect of the present invention is characterized by comprising: a CPU; a fan which cools the CPU; means for accepting an input operation by a user; means for determining a number of revolutions of the fan according to the input operation accepted by the means for accepting the input operation; and means for controlling the number of revolutions of the fan on the basis of a determined number of revolutions.

A fan control method for monitoring the temperature of a CPU and controlling the number of revolutions of a fan which cools the CPU, according to a second aspect of the present invention, is characterized by comprising: accepting an input operation by a user; setting a maximum number of revolutions of the fan according to the accepted input operation; and controlling the number of revolutions of the fan on the basis of the determined maximum number of revolutions.

### BRIEF DESCRIPTION OF THE SEVERAL VIEWS OF THE DRAWING

FIG. 1 is a block diagram showing a configuration of an information processing apparatus according to an embodiment of the invention;

FIG. 2 is a diagram showing an outline structural example of an information processing apparatus according to an embodiment of the invention, and a key layout example for controlling the number of revolutions of a fan;

FIG. 3 is an operation explanatory diagram of fan revolution control according to an embodiment of the invention;

FIG. 4 is a flowchart showing a processing procedure according to a first embodiment of the invention;

FIG. 5 is a flowchart showing a processing procedure according to a second embodiment of the invention;

FIG. 6 is a flowchart showing a processing procedure according to a third embodiment of the invention;

FIG. 7 is a diagram showing a structural example of a setting table for the maximum number of revolutions according to the third embodiment;

FIG. 8 is a diagram showing another structural example of the setting table for the maximum number of revolutions according to the third embodiment; and

FIGS. 9A and 9B are diagrams showing a display example of a user interface screen according to the third embodiment.

### DETAILED DESCRIPTION OF THE INVENTION

Hereinafter, the embodiment of the present invention will be explained referring to the drawings.

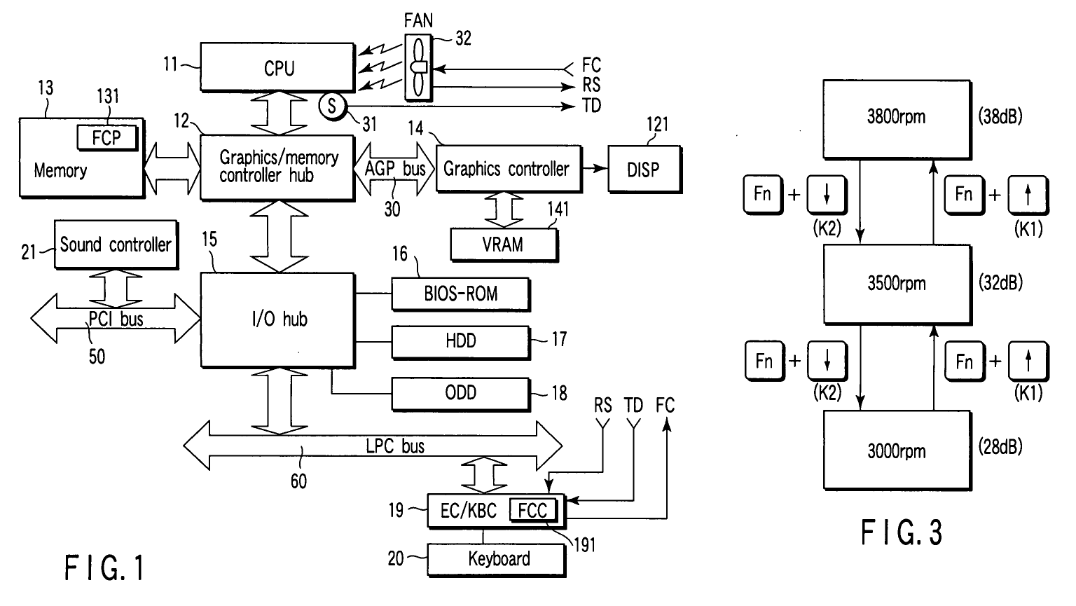

FIG. 1 shows a configuration of an information processing apparatus according to an embodiment of the invention. This is an example of a battery-driven portable personal computer of notebook type, and the configuration of its computer system is described.

This computer system comprises, as shown in FIG. 1, a CPU 11, a graphic memory controller hub 12, a memory (main memory) 13, a graphics controller 14, a VRAM 141, an I/O hub 15, a BIOS-ROM 16, a hard disk drive (HDD) 17, an optical disk drive (ODD) 18, a keyboard embedded controller (EC/KBC) 19, a keyboard 20, a sound controller 21, a display device (DISP) 121, a CPU temperature sensor 31, a cooling fan 32, and the like. Further, the memory 13 stores a fan control utility program (FCP) 131, and the keyboard embedded controller 19 stores a fan control program (FCC) 191.

The CPU 11 controls the operation of this computer. The CPU 11 executes various processings by the operating system (OS), application programs, utility programs, and the like loaded from the hard disk drive 17 into the main memory 13. In the embodiment according to the invention, the CPU 11 executes the processing of the fan control utility program (FCP) 131 stored in the memory 13, operates in cooperation with the processing of the fan control program (FCC) 191 executed by the keyboard embedded controller 19, and provides an operating and setting environment for the user to set the maximum number of revolutions of the fan 32.

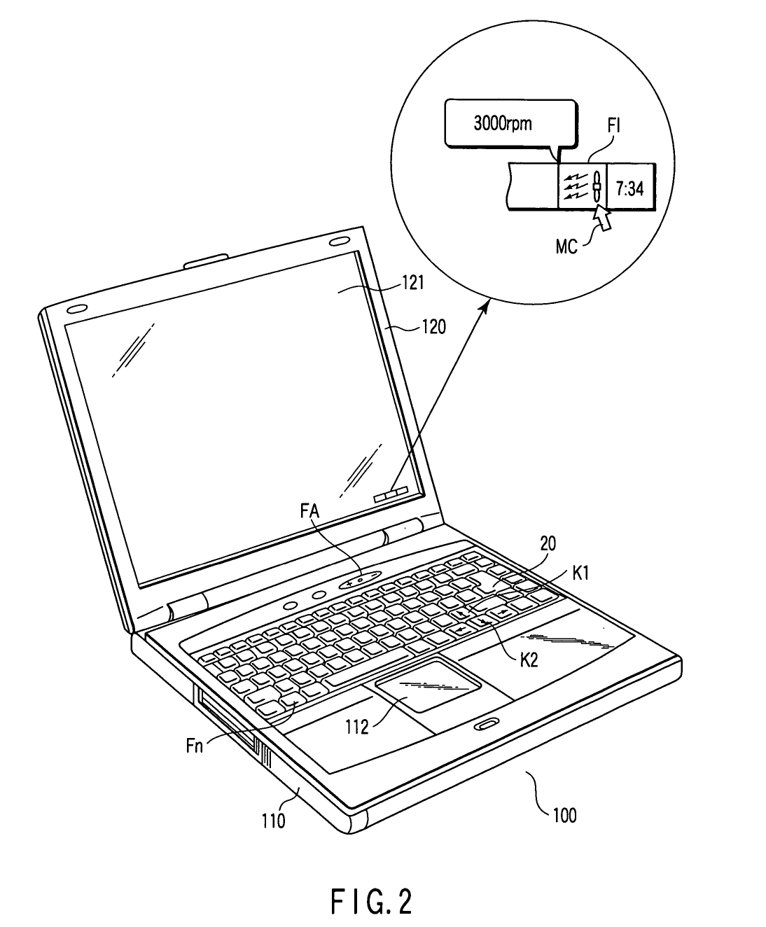

The graphics controller 14 drives and controls the display device (DISP) 121 under the control of the operating system (OS) executed by the CPU 11, and also drives and controls an external display device (not shown). In the embodiment according to the invention, the display device 121 shows a user interface screen for setting the maximum number of revolutions of the fan 32 according to the fan control utility program (FCP) 131 under the control of the CPU 11, and also displays a user interface screen for informing the user of the set maximum number of revolutions of the fan 32 (see FIGS. 2, 7, 8, 9A, and 9B).

The keyboard embedded controller 19 is a one-chip microcomputer in which an embedded controller for electric power control is integrated with a keyboard controller for controlling the keyboard 13. Further, the keyboard embedded controller 19 monitors the temperature of the CPU 11 detected by the CPU temperature sensor (S) 31, and controls the number of revolutions of the fan 32 for cooling the CPU 11. At this time, the keyboard embedded controller 19 acquires data (RS) showing the number of revolutions of the fan 32 from the fan 32, sends out a control signal of the number of revolutions (FC) to the fan 32, and controls the number of revolutions of the fan 32.

In this manner, the keyboard embedded controller 19 executes the function of setting the maximum number of revolutions of the fan 32 described below and controls the number of revolutions of the fan 32 according to the maximum number of revolutions determined by this setting function, in cooperation with the fan control utility program (FCP) 131 stored in the memory 13 and executed by the CPU 11, according to the fan control utility program (FCP) 13 stored in the internal memory (see FIGS. 2 to 8).

FIG. 2 is a diagram showing an outline structure of the information processing apparatus according to the embodiment of the invention, a key layout example for setting the maximum number of revolutions of the fan 32, and an example of user interface displaying the set maximum number of revolutions of the fan 32. In FIG. 2, an example of a notebook type personal computer is shown. A computer 100 according to the embodiment of the invention shown in FIG. 2 comprises a computer main body 110, and a display unit (display casing) 120. The display unit 120 incorporates a display device (DISP) 121 using LCD. The display unit 120 incorporating the display device 121 is installed in the computer main body 110 so as to be free to fold between the open position and the closed position.

In the embodiment of the invention, the display device 121 incorporated in the display unit 120 displays a user interface screen for setting the maximum number of revolutions of the fan 32, and a user interface screen for informing the user of the determined maximum number of revolutions of the fan 32. FIG. 2 shows an example of selective display of a system tray icon (F1) for informing the user of the current set value of the maximum number of revolutions of the fan 32. By moving a mouse cursor (MC) onto the system tray icon (F1), the current set value of the maximum number of revolutions of the fan 32 (3000 rpm in this example) is displayed in the pop-up window of the system tray icon. Display control of this user interface screen is realized by executing the fan control utility program (FCP) 131 stored in the memory 13 by the CPU 11.

The computer main body 110 is a thin box body, and the keyboard 20 is disposed on its top, and an arm rest is formed behind the keyboard 20. A touch panel 112 is formed in the center of the arm rest.

In the example shown in FIG. 2, a function extension key (Fn), an up-cursor key (K1), and a down-cursor key (K2) provided in the keyboard 20 are used as operation switches for setting the maximum number of revolutions of the fan 32. In this example, with the function extension key (Fn) being depressed, by operating the up-cursor key (K1) once, the maximum number of revolutions of the fan 32 is increased by one step. With the function extension key (Fn) being depressed, by operating the down-cursor key (K2) once, the maximum number of revolutions of the fan 32 is decreased by one step.

Ahead of the keyboard 20, there is a toggle type +/− operation switch (FA) used in special operation. Like the combined operation of the function extension key (Fn) with the up-cursor key (F1) and down-cursor key (K2), this key (FA) is used as operation switch for setting the maximum number of revolutions of the fan 32. For example, when the operation switch (FA) is operated once in the + direction, an instruction is given to increase the maximum number of revolutions of the fan 32 by one step, and when operated once in the − direction, an instruction is given to decrease the maximum number of revolutions of the fan 32 by one step.

FIG. 3 is a diagram showing an example of operation of setting the maximum number of revolutions of the fan 32 according to the embodiment of the invention. FIG. 3 shows an example of changing over in two steps. For example, the maximum number of revolutions 3800 rpm (noise: 38 db) conventionally predetermined as eigenvalue is set as reference setting of maximum number of revolutions, and when the down-cursor key (K2) is operated once with the function extension key (Fn) depressed, the maximum number of revolutions of the fan 32 is decreased by one step to become 3500 rpm (noise: 32 db). Further, when the down-cursor key (K2) is operated once again with the function extension key (Fn) depressed, the maximum number of revolutions of the fan 32 is further decreased by one step to become 3000 rpm (noise: 28 db). The number of steps of changing over can be set optionally in view of usability. Suppose the maximum number of revolutions of the fan 32 is set at 3000 rpm, when the up-cursor key (K1) is operated once with the function extension key (Fn) depressed, the maximum number of revolutions of the fan 32 is increased by one step to become 3500 rpm. Further, when the up-cursor key (K1) is operated once again with the function extension key (Fn) depressed, the maximum number of revolutions of the fan 32 is further increased by one step to become 3800 rpm. Herein, the function of setting the maximum number of revolutions of the fan is explained by combined operation of the function extension key (Fn) with the up-cursor key (F1) and down-cursor key (K2), but the maximum number of revolutions of the fan can be also set by the operation switch (FA).

The maximum number of revolutions of fan set by the user is displayed and easily confirmed on the screen of the display device 121 as shown in FIG. 2 by moving the mouse cursor (MC) onto the system tray icon (F1).

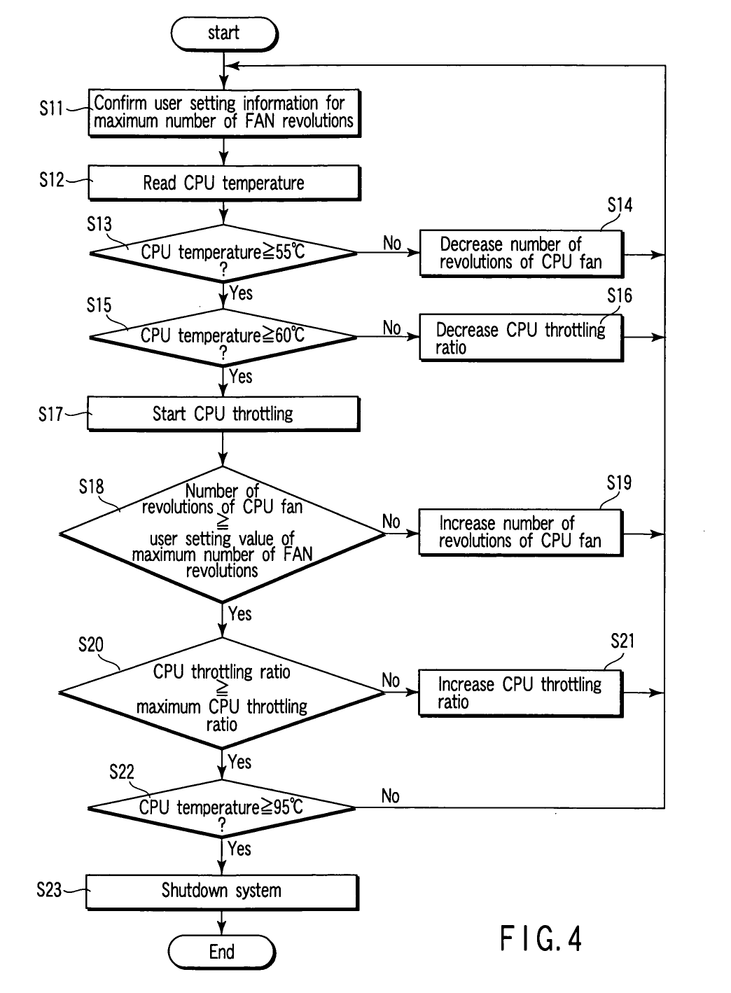

FIG. 4 shows the procedure of processing of controlling the maximum number of revolutions of the fan 32 according to the maximum number of revolutions set by the function of setting the maximum number of revolutions of the fan according to a first embodiment of the invention. This processing is executed by executing the processing of the fan control program (FCC) 191 by the microprocessor of the keyboard embedded controller 19.

In the processing of the first embodiment shown in FIG. 4, it is first confirmed that the current setting of the maximum number of revolutions of the fan 32 is stored in the fan revolution control register (not shown) (step S11 in FIG. 4). The temperature (TD) of the CPU 11 detected by the CPU temperature sensor (S) 31 is read in (step S12 in FIG. 4). It is then determined whether or not the temperature (TD) of the CPU 11 has reached a first set temperature (55° C.) stored in the fan revolution control register (step S13 in FIG. 4).

In step S13, if the temperature (TD) of the CPU 11 has not reached the first set temperature (55° C.) stored in the fan revolution control register (No in step S13 in FIG. 4), the number of revolutions of the fan 32 is decreased (step S14 in FIG. 4).

In step S13, if the temperature (TD) of the CPU 11 has reached the first set temperature (55° C.) stored in the fan revolution control register (Yes in step S13 in FIG. 4), successively, it is determined whether or not the temperature (TD) of the CPU 11 has reached a second set temperature (60° C.) stored in the fan revolution control register (step S15 in FIG. 4).

In step S15, if the temperature (TD) of the CPU 11 has reached the second set temperature (60° C.) stored in the fan revolution control register (Yes in step S15 in FIG. 4), throttling (operation mode with an intermittent pause time) of the CPU 11 is started (step S17 in FIG. 4), and it is determined whether or nor the number of revolutions (RS) of the fan 32 has reached the maximum number of revolutions stored in the fan revolution control register (step S18 in FIG. 4).

Herein, if the user has already set the maximum number of revolutions of the fan 32 by the operation of setting the maximum number of revolutions, on the basis of this maximum number of revolutions set by the user, it is determined whether or not the number of revolutions (RS) of the fan 32 has reached the set maximum number of revolutions.

In step S18, if the number of revolutions (RS) of the fan 32 has not reached the maximum number of revolutions stored in the fan revolution control register (the maximum number of revolutions set by the user) (No in step S18 in FIG. 4), the number of revolutions of the fan 32 is increased (step S19 in FIG. 4).

In step S18, if the number of revolutions (RS) of the fan 32 has reached the maximum number of revolutions stored in the fan revolution control register (the maximum number of revolutions set by the user) (Yes in step S18 in FIG. 4), it is determined whether or not the throttling ratio of the CPU 11 has reached the permissible maximum throttling ratio (step S20 in FIG. 4).

In step S20, if the throttling ratio of the CPU 11 has reached the permissible maximum throttling ratio of the CPU (performance (operating speed) lowest limit state) (Yes in step S20 in FIG. 4), successively, it is determined whether or not the temperature (TD) of the CPU 11 has reached a third set temperature (95° C.) stored in the fan revolution control register (step S22 in FIG. 4).

In step S22, if the temperature (TD) of the CPU 11 has reached the third set temperature (95° C.) stored in the fan revolution control register (Yes in step S22 in FIG. 4), the system is shut down (step S23 in FIG. 4). If the temperature (TD) of the CPU 11 has not reached the third set temperature (95° C.) stored in the fan revolution control register (No in step S22 in FIG. 4), the same processing is executed repeatedly (steps S11, S12, . . . in FIG. 4). In step S15, if the temperature (TD) of the CPU 11 has not reached the second set temperature (60° C.) stored in the fan revolution control register (No in step S15 in FIG. 4), the throttling ratio of the CPU 11 is lowered (the pause time is shortened) (step S16 in FIG. 4). In step S20, if the throttling ratio of the CPU 11 has not reached the permissible maximum throttling ratio of the CPU (No in step S20 in FIG. 4), the throttling ratio of the CPU 11 is raised (the pause time is extended) (step S21 in FIG. 4), and an efficient CPU throttling control is executed within a predetermined set temperature range.

In this manner, the number of revolutions of the fan 32 is controlled according to the maximum number of revolutions set by the user. Thus, the system performance and operating environment of low fan noise can be changed over appropriately by a simple operation by the user.

FIG. 5 shows the procedure of processing of controlling the maximum number of revolutions of the fan 32 according to the maximum number of revolutions determined by the function of setting the maximum number of revolutions of the fan according to a second embodiment of the invention.

In the processing of the second embodiment shown in FIG. 5, it is first confirmed that the current setting of the maximum number of revolutions of the fan 32 is stored in the fan revolution control register (not shown) (step S31 in FIG. 5). The temperature (TD) of the CPU 11 detected by the CPU temperature sensor (S) 31 is read in (step S32 in FIG. 5). It is then determined whether or not the temperature (TD) of the CPU 11 has reached the first set temperature (55° C.) stored in the fan revolution control register (step S33 in FIG. 5).

In step S33, if the temperature (TD) of the CPU 11 has reached the first set temperature (55° C.) stored in the fan revolution control register (Yes in step S33 in FIG. 5), successively, it is determined whether or not the temperature (TD) of the CPU 11 has reached the second set temperature (60° C.) stored in the fan revolution control register (step S35 in FIG. 5).

In step S35, if the temperature (TD) of the CPU 11 has not reached the second set temperature (60° C.) stored in the fan revolution control register (No in step S35 in FIG. 5), the number of revolutions of the fan 32 is decreased (step S36 in FIG. 5).

In step S35, if the temperature (TD) of the CPU 11 has reached the second set temperature (60° C.) stored in the fan revolution control register (Yes in step S35 in FIG. 5), throttling of the CPU 11 is started (step S37 in FIG. 5). Successively, it is determined whether or not the throttling ratio of the CPU 11 has reached the permissible maximum throttling ratio of the CPU (step S38 in FIG. 5).

In step S38, if the throttling ratio of the CPU 11 has reached the permissible maximum throttling ratio of the CPU 11 (Yes in step S38 in FIG. 5), successively, it is determined whether or not the number of revolutions (RS) of the fan 32 has reached the maximum number of revolutions stored in the fan revolution control register (step S40 in FIG. 5). Herein, if the number of revolutions (RS) of the fan 32 has reached the maximum number of revolutions stored in the fan revolution control register (Yes in step S40 in FIG. 5), successively it is determined whether or not the temperature (TD) of the CPU 11 has reached the third set temperature (95° C.) stored in the fan revolution control register (step S42 in FIG. 5).

In step S42, if the temperature (TD) of the CPU 11 has reached the third set temperature (95° C.) stored in the fan revolution control register (Yes in step S42 in FIG. 5), the system is shut down (step S43 in FIG. 5). If the temperature (TD) of the CPU 11 has not reached the third set temperature (95° C.) stored in the fan revolution control register (No in step S42 in FIG. 5), the same processing is executed repeatedly (steps S31, S32, . . . in FIG. 5). In step S33, if the temperature (TD) of the CPU 11 has not reached the first set temperature (55° C.) stored in the fan revolution control register (No in step S33 in FIG. 5), the throttling ratio of the CPU 11 is lowered (step S36 in FIG. 5). In step S33, if the throttling ratio of the CPU 11 has not reached the permissible maximum throttling ratio of the CPU 11 (No in step S38 in FIG. 5), the throttling ratio of the CPU 11 is raised (step S39 in FIG. 5), and an efficient CPU throttling control is executed within a predetermined set temperature range.

Also in the control of the number of revolutions of the fan according to the second embodiment, the number of revolutions of the fan 32 is controlled according to the maximum number of revolutions set by the user. Thus, if the operating environment of lower fan noise is more desired than the system performance, the operating environment of lower fan noise can be provided by a simple operation by the user.

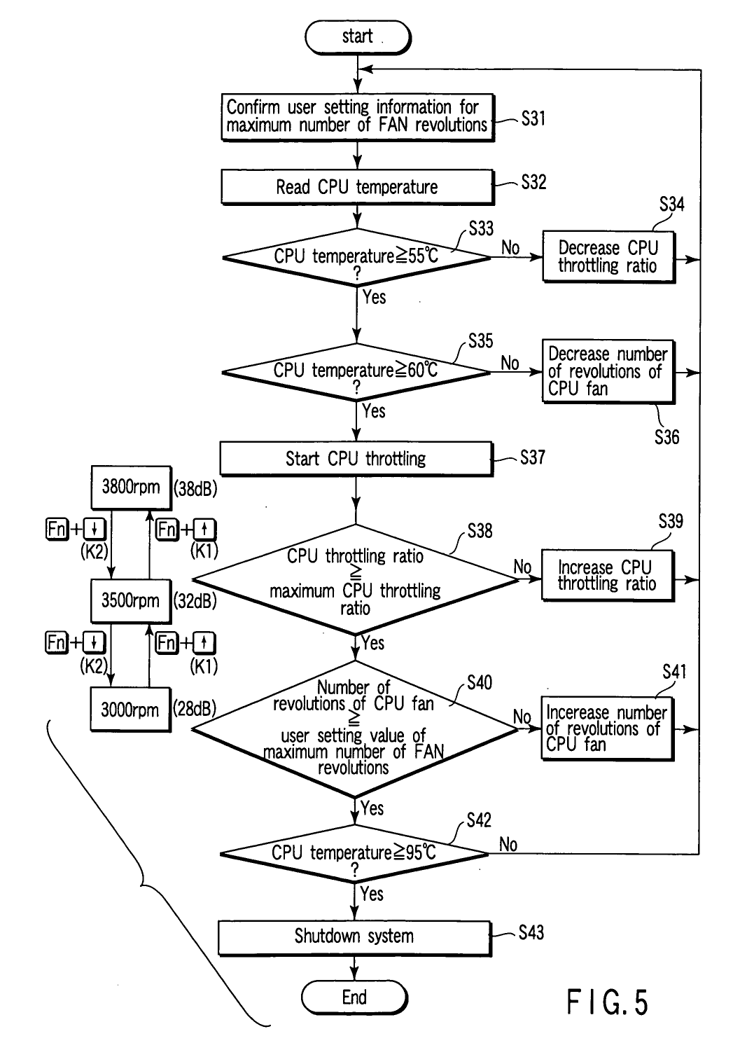

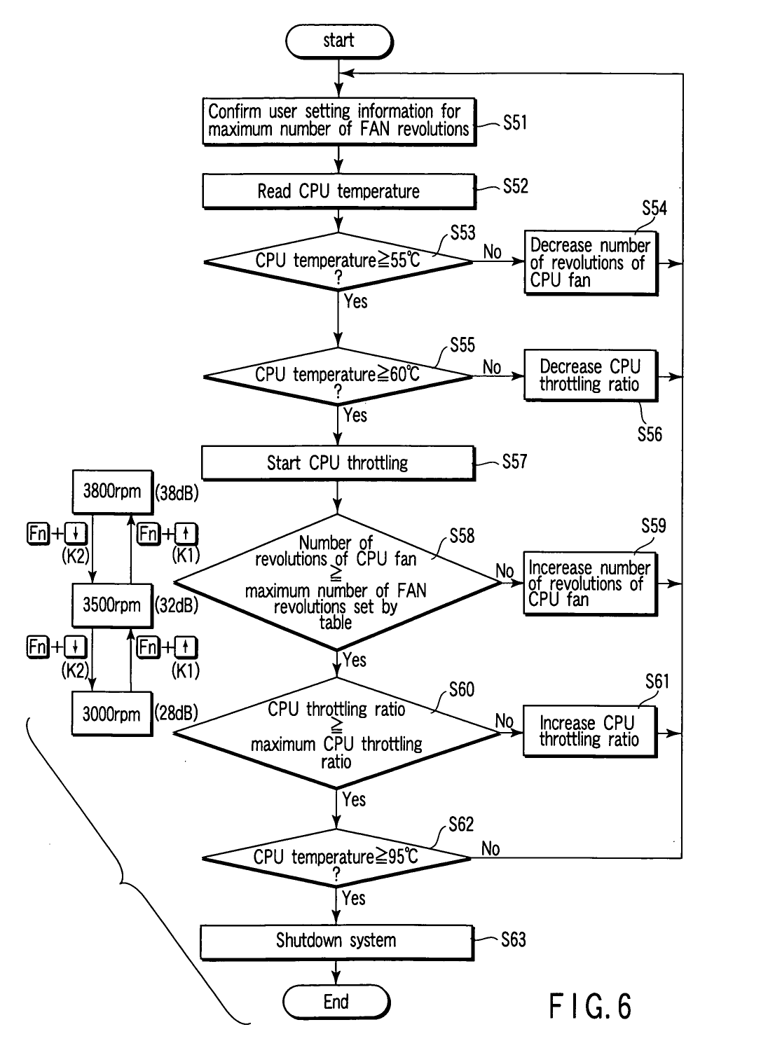

FIG. 6 shows the procedure of processing of controlling the maximum number of revolutions of the fan 32 according to the maximum number of revolutions determined by the function of setting the maximum number of revolutions of the fan according to a third embodiment of the invention.

The third embodiment shown in FIG. 6 differs particularly from the first embodiment in the following. As compared with the first embodiment in which the maximum number of revolutions is set and changed in gradual steps depending on the number of times of user's operation of key or switch, the third embodiment is characterized by using a setting table for the maximum number of revolutions to control the number of revolutions of the fan 32 by the function of setting the maximum number of revolutions of the fan 32 and the maximum number of revolutions set by this setting function.

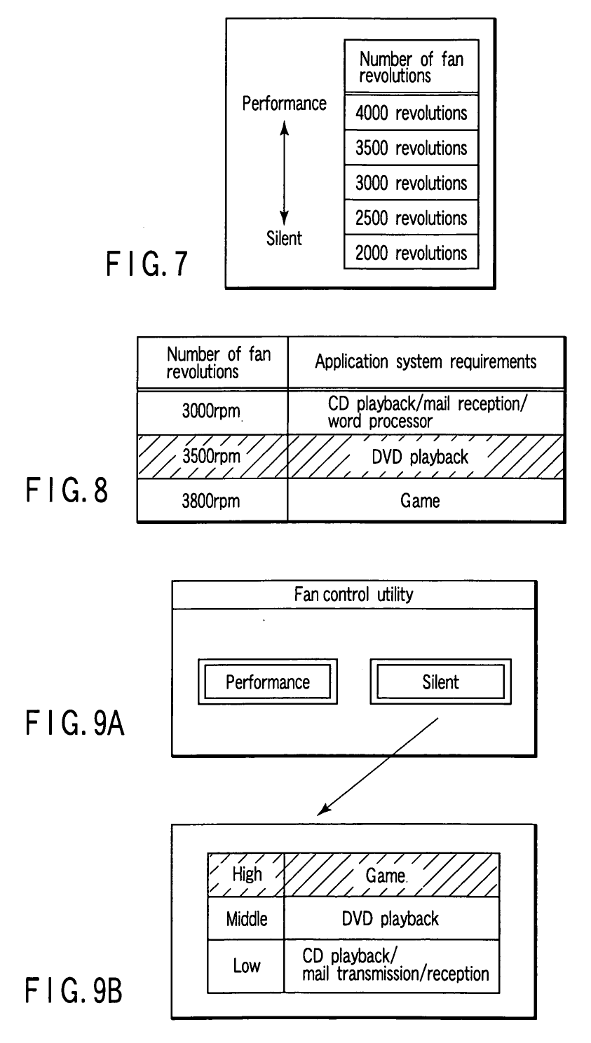

Examples of the setting table for the maximum number of revolutions presented to the user are shown in FIGS. 7 to 9B. FIG. 7 shows an example of display of the setting table for the maximum number of revolutions allowing to select the maximum number of revolutions of the fan 32 from five steps. FIG. 8 shows an example of display of the setting table for the maximum number of revolutions allowing the user to select a desired maximum number of revolutions by correspondence between the maximum number of revolutions of the fan 32 and the application guide. FIGS. 9A and 9B show display examples of a user interface screen. As shown in FIG. 9A, there is displayed a fan control utility screen having an operation button for selecting a performance mode for preferring the performance, and an operation button for selecting a silent mode for preferring reduction of fan noise. When the operation button for selecting the silent mode is manipulated on the screen, an operation screen for selecting the maximum number of revolutions relating the maximum number of revolutions of the fan 32 (high/medium/low) with the application guide is displayed as shown in FIG. 9B.

The user interface screen for setting the maximum number of revolutions of the fan 32, and the user interface screen for informing the user of the set maximum number of revolutions of the fan 32 are shown on the display device 121 by executing the fan control utility program (FCP) 131 stored in the memory 13 by the CPU 11. Further, the data of the maximum number of revolutions selected and operated on the setting table for the maximum number of revolutions shown on the display device 121 is noticed to the keyboard embedded controller 19. The keyboard embedded controller 19 controls the number of revolutions of the fan 32 according to the maximum number of revolutions noticed from the CPU 11.

In the processing of the third embodiment shown in FIG. 6, in step S58, it is determined whether or not the number of revolutions (RS) of the fan 32 has reached the maximum number of revolutions set by the user on the table (operation screen). Except for this processing, other steps (S51 to S57, S59 to S63) can be easily estimated from the operation of the first embodiment, and explanation of such processing is omitted herein.

Also in the control of the number of revolutions of the fan in the third embodiment, the number of revolutions of the fan 32 is controlled according to the maximum number of revolutions set by the user. Thus, if the operating environment of lower fan noise is more desired than the system performance, the operating environment of the silent mode of lower fan noise can be provided by a simple operation by the user.

The embodiment of the invention provides a setting environment allowing the user to change the maximum number of revolutions of the fan easily. Therefore, the level of the noise due to high speed revolution of the fan can be controlled by the user, and if the operating environment of lower fan noise is more desired than the system performance, the operating environment of lower fan noise can be provided by a simple operation by the user.

That is, the embodiment of the invention provides an information processing apparatus having a fan control function for monitoring the temperature of the CPU and controlling the number of revolutions of the fan for cooling the CPU, in which according to the operation input of the user, the maximum number of revolutions of the fan is decided, and the number of revolutions of the fan is controlled according to the decided maximum number of revolutions.

As a result, the user can freely set and control the level of noise due to high speed revolution of the fan. If the operating environment of lower fan noise is more desired than the system performance, the operating environment of lower fan noise can be provided by a simple operation by the user.

According to the embodiments of the invention, the information processing apparatus having a function of controlling and setting the number of revolutions of the fan easily by user's operation can be provided. Therefore, the operating environment of system performance or low fan noise can be changed over appropriately by user's simple operation.

Additional advantages and modifications will readily occur to those skilled in the art. Therefore, the present invention in its broader aspects is not limited to the specific details, representative devices, and illustrated examples shown and described herein. Accordingly, various modifications may be made without departing from the spirit or scope of the general inventive concept as defined by the appended claims and their equivalents.

What is claimed is:

1. An information processing apparatus comprising:
a CPU;
a fan which cools the CPU;
means for accepting an input operation by a user;
means for determining a number of revolutions of the fan according to the input operation accepted by the means for accepting the input operation; and
means for controlling the number of revolutions of the fan on the basis of a determined number of revolutions.

2. The information processing apparatus according to claim 1, wherein the means for controlling the number of revolutions comprises means for monitoring a temperature of the CPU, and controlling an operating speed of the CPU such that the temperature is controlled within an permissible temperature.

3. The information processing apparatus according to claim 2, wherein
the means for accepting the input operation accepts the input operation by a predetermined function key operation or a switch operation of the user, and
the means for controlling the number of revolutions comprises means for increasing or decreasing a maximum number of revolutions of the fan step by step according to a number of times of key or switch operation accepted by the means for accepting the input operation.

4. The information processing apparatus according to claim 2, wherein the means for monitoring the temperature compares the number of revolutions of the fan and the maximum number of revolutions determined according to the input operation accepted by the means for accepting the input operation, and lowers the operating speed of the CPU and decreases the number of revolutions of the fan when the number of revolutions of the fan has reached the maximum number of revolutions.

5. The information processing apparatus according to claim 1, wherein the means for controlling the number of revolutions comprises user interface means for presenting to the user the maximum number of revolutions of the fan determined by the operation input of the user.

6. The information processing apparatus according to claim 2, wherein the means for controlling the number of revolutions comprises a setting table for the number of revolutions of the fan defining plural levels of maximum number of revolutions of the fan, and determines the maximum number of revolutions of the fan according to the input operation accepted by the means for accepting the input operation by referring to the setting table of number of revolutions of the fan.

7. The information processing apparatus according to claim 6, wherein the means for controlling the number of revolutions comprises user interface means for displaying an operation screen according to the setting table for the number of revolutions of the fan.

8. A fan control method for monitoring the temperature of a CPU and controlling the number of revolutions of a fan which cools the CPU, the method comprising:
accepting an input operation by a user;
setting a maximum number of revolutions of the fan according to the accepted input operation; and
controlling the number of revolutions of the fan on the basis of the determined maximum number of revolutions.

9. The fan control method according to claim 8, wherein the setting the maximum number of revolutions of the fan includes increasing or decreasing the maximum number of revolution of the fan step by step according to the number of times of input operation by a predetermined function key operation or switch operation by the user.

10. The fan control method according to claim 9, wherein the controlling the number of revolutions of the fan includes comparing the number of revolutions of the fan and the maximum number of revolutions determined according to the accepted input operation; and lowering the operating speed of the CPU and decreasing the number of revolutions of the fan when the number of revolutions of the fan is determined to have reached the maximum number of revolutions.

11. The fan control method according to claim 9, wherein the controlling the number of revolutions of the fan includes referring to a setting table for the number of revolutions of the fan showing correspondence between the operation input data and the maximum number of revolutions of the fan, setting the maximum number of revolutions of the fan according to the accepted operation input, and controlling the number of revolutions of the fan on the basis of the determined maximum number of revolutions.
